(19) United States
(12) Patent Application Publication
(10) Pub. No.: US 2009/0325078 A1
(43) Pub. Date: Dec. 31, 2009

(54) HOLOGRAPHIC RECORDING MEDIUM

(75) Inventors: Gary Charles Davis, Albany, NY (US); Moitreyee Sinha, Niskayuna, NY (US); Brian Lee Lawrence, Niskayuna, NY (US); Christoph Georg Erben, Clifton Park, NY (US); Mark Allen Cheverton, Mechanicville, NY (US); Sumeet Jain, Niskayuna, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 12/164,147

(22) Filed: Jun. 30, 2008

(51) Int. Cl. G03F 7/00

(52) U.S. Cl. 430/2

(57) ABSTRACT

A holographic recording medium including an optically transparent substrate is provided. The optically transparent substrate includes an optically transparent plastic material and a photochemically active dye. The optically transparent substrate has an absorbance of greater than 1 at a wavelength that is in a range of from about 300 nanometers to about 1000 nanometers. The holograms recorded in the optically transparent substrate are capable of having diffraction efficiencies of greater than about 20 percent. The holographic recording medium may include a photo-product. A method of making the holographic recording medium, an optical writing and reading method, a method for using a holographic recording article, and a method of manufacturing the holographic recording medium are provided.

### TECHNICAL FIELD

The invention includes embodiments that may relate to a holographic recording medium. The invention includes embodiments that may relate to a method for making and using a holographic recording medium.

### DISCUSSION OF ART

Holographic recording is the storage of information in the form of holograms. The information can be stored in different forms including binary data, images, bar-codes, and gratings. Holograms are images of three-dimensional interference pattern. These patterns may be created by the intersection of two beams of light in a photosensitive medium. A difference of volume holographic recording relative to surface-based storage formats is that a large number of holograms may be stored in an overlapping manner in the same volume of the photosensitive medium using a multiplexing technique. This multiplexing technique may vary the signal and/or reference beam angle, wavelength, or medium position. However, an impediment towards the realization of holographic recording as a viable technique has been the development of a suitable recording medium.

Recent holographic recording materials work has led to the development of dye-doped polymeric materials. The sensitivity of a dye-doped data storage material may depend on the concentration of the dye, the dye's absorption cross-section at the recording wavelength, the quantum efficiency of the photochemical transition, and the index change of the dye molecule for a unit dye density. However, as the product of dye concentration and the absorption cross-section increases, the recording medium (for example, a holographic film) may become opaque, which may complicate both recording and readout.

It may be desirable to have a holographic recording medium that has characteristics and properties that differ from those currently available.

### BRIEF DESCRIPTION

In one embodiment, a holographic recording medium is provided. The holographic recording medium includes an optically transparent substrate. The optically transparent substrate includes an optically transparent plastic material and a photochemically active dye. The optically transparent substrate has an absorbance of greater than 1 at a wavelength that is in a range of from about 300 nanometers to about 1000 nanometers. The holograms recorded in the optically transparent substrate are capable of having diffraction efficiencies of greater than about 20 percent.

In one embodiment, a holographic recording medium is provided. The holographic recording medium includes an optically transparent substrate. The optically transparent substrate includes an optically transparent plastic material, a photochemically active dye, and a photo-product thereof. The optically transparent substrate has an absorbance of greater than 1 at a wavelength that is in a range of from about 300 nanometers to about 1000 nanometers. The holograms recorded in the optically transparent substrate are capable of having diffraction efficiencies of greater than about 20 percent. The photo-product is patterned within the optically transparent substrate to provide an optically readable datum contained within a volume of the holographic recording medium.

In one embodiment, a holographic recording medium is made. The method includes irradiating an optically transparent substrate including a photochemically active dye with an incident light at a wavelength in a range of from about 300 nanometers to about 1000 nanometers at which the optically transparent substrate has an absorbance of greater than 1, and resulting in forming the holographic recording medium including an optically readable datum and a photo-product of a photochemically active dye. The holograms recorded in the optically transparent substrate are capable of having diffraction efficiencies of greater than about 20 percent.

In one embodiment, an optical writing and reading method is provided. The method includes patterning simultaneously a holographic recording medium with a signal beam possessing data and a reference beam, and thereby partly converting the photochemically active dye into a photo-product, storing the data in the signal beam as a hologram in the holographic recording medium, and contacting the holographic recording medium with a read beam and reading the data contained by diffracted light from the hologram. The holographic recording medium includes an optically transparent substrate. The optically transparent substrate includes an optically transparent plastic material and a photochemically active dye. The optically transparent substrate has an absorbance of greater than 1 at a wavelength that is in a range of from about 300 nanometers to about 1000 nanometers. The holograms recorded in the optically transparent substrate are capable of having diffraction efficiencies of greater than about 20 percent.

In one embodiment, a method includes subjecting a holographic recording medium in the holographic recording article to an electromagnetic radiation having a first wavelength, forming a modified optically transparent substrate including at least one photo-product of the photochemically active dye, and at least one optically readable datum stored as a hologram, and contacting the holographic recording medium in the article with electromagnetic energy having a second wavelength to read the hologram. The holographic recording medium includes an optically transparent substrate. The optically transparent substrate includes an optically transparent plastic material, and a photochemically active dye. The optically transparent substrate has an absorbance of greater than about 1 at a wavelength that is in a range of from about 300 nanometers to about 1000 nanometers. The optically transparent substrate has a diffraction efficiency of greater than about 20 percent.

In one embodiment, a method includes forming a film or an injection molded part of an optically transparent substrate. The optically transparent substrate includes an optically transparent plastic material and a photochemically active dye. The optically transparent substrate has an absorbance of greater than 1 at a wavelength in a range of from about 300 nanometers to about 1000 nanometers. The holograms recorded in the optically transparent substrate are capable of having diffraction efficiencies of greater than about 20 percent.

In one embodiment, a holographic recording medium is provided. The holographic recording medium includes an optically transparent substrate. The optically transparent substrate includes an optically transparent plastic material and a photochemically active dye. The optically transparent substrate has an absorbance of greater than 1 when irradiated with an incident light at a wavelength that is in a range of from about 300 nanometers to about 1000 nanometers to write a hologram. The hologram in the optically transparent substrate has a diffraction efficiency of greater than about 20 percent.

### DETAILED DESCRIPTION

The invention includes embodiments that may relate to a holographic recording medium. The invention includes embodiments that may relate to a method for making and using a holographic recording medium.

In one embodiment, a holographic recording medium is provided. The holographic recording medium includes an optically transparent substrate. The optically transparent substrate includes an optically transparent plastic material and a photochemically active dye. The optically transparent substrate has an absorbance of greater than 1 at a wavelength that is in a range of from about 300 nanometers to about 1000 nanometers. The holograms recorded in the optically transparent substrate are capable of having diffraction efficiencies of greater than about 20 percent.

In one embodiment, the holographic recording medium may have a data storage capacity that is greater than about 1. As defined herein, the phrase data storage capacity relates to the capacity of a holographic recording medium as given by the M/#. M/# can be measured as a function of the total number of multiplexed holograms that can be recorded at a volume element of the data recording medium at a given diffraction efficiency. M/# depends upon various parameters, such as the change in refractive index (An), the thickness of the medium, and the dye concentration. These terms are described further in this disclosure. The M# is defined as shown in equation 1:

$$M / \# = {\sum }_{i = 1}^{N} \sqrt{{η}_{i}} \qquad Equation 1$$

where ηᵢ is diffraction efficiency of the i^{th} hologram, and N is the number of recorded holograms. The experimental setup for M/# measurement for a test sample at a chosen wavelength, for example, at 532 nanometers or 405 nanometers involves positioning the testing sample on a rotary stage that is controlled by a computer. The rotary stage has a high angular resolution, for example, about 0.0001 degree. An M/# measurement involves two steps: recording and readout. At recording, multiple plane-wave holograms are recorded at the same location on the same sample. A plane wave hologram is a recorded interference pattern produced by a signal beam and a reference beam. The signal and reference beams are coherent to each other. They are both plane-waves that have the same power and beam size, incident at the same location on the sample, and polarized in the same direction. Multiple plane-wave holograms are recorded by rotating the sample. Angular spacing between two adjacent holograms is about 0.2 degree. This spacing is chosen so that their impact to the previously recorded holograms, when multiplexing additional holograms, is minimal and at the same time, the usage of the total capacity of the media is efficient. Recording time for each hologram is generally the same in M/# measurements. At readout, the signal beam is blocked. The diffracted signal is measured using the reference beam and an amplified photo-detector. Diffracted power is measured by rotating the sample across the recording angle range with a step size of about 0.004 degree. The power of the reference beam used for readout may be about 2-3 orders of magnitude smaller than that used at recording. This is to minimize hologram erasure during readout while maintaining a measurable diffracted signal. From the diffracted signal, the multiplexed holograms can be identified from the diffraction peaks at the hologram recording angles. The diffraction efficiency of the i^{th} hologram, η_{i,}, is then calculated by using Equation 2:

$${η}_{i} = \frac{{P}_{i , diffracted}}{{P}_{reference \cdot }} \qquad Equation 2$$

where P_{i,} diffracted is the diffracted power of the i^{th} hologram. M/# is then calculated using the diffraction efficiencies of the holograms and Equation 1. Thus, a holographic plane wave characterization system may be used to test the characteristics of the data recording material, especially multiplexed holograms. Further, the characteristics of the data recording material can also be determined by measuring the diffraction efficiency.

As used herein, the term “volume element” means a three dimensional portion of the total volume of an optically transparent substrate or a modified optically transparent substrate.

As used herein the term “optically transparent substrate” means a substrate that is capable of transmitting at least part of the incident light which is at a wavelength that is in a range of from about 300 nanometers to about 1000 nanometers.

As defined herein, the term “optically readable datum” is made up of one or more volume elements of a first or a modified optically transparent substrate containing a “hologram” of the data to be stored. The refractive index within an individual volume element may be constant throughout the volume element, as in the case of a volume element that has not been exposed to electromagnetic radiation, or in the case of a volume element in which the photochemically active dye has been reacted to the same degree throughout the volume element. Some volume elements that have been exposed to electromagnetic radiation during the holographic data writing process may contain a complex holographic pattern. And, the refractive index within the volume element may vary across the volume element. In instances in which the refractive index within the volume element varies across the volume element, it is convenient to regard the volume element as having an “average refractive index” which may be compared to the refractive index of the corresponding volume element prior to irradiation. Thus, in one embodiment an optically readable datum includes at least one volume element having a refractive index that is different from the corresponding volume element of the optically transparent substrate prior to irradiation. Locally changing the refractive index of the data recording medium in a graded fashion (continuous sinusoidal variations), rather than discrete steps, and then using the induced changes as diffractive optical elements allows data storage.

The capacity to store data as holograms (M/#) may be directly proportional to the ratio of the change in refractive index per unit dye density (Δn/N₀) at the wavelength used for reading the data to the absorption cross section (σ) at a given wavelength used for writing the data as a hologram. The refractive index change per unit dye density is given by the ratio of the difference in refractive index of the volume element before irradiation minus the refractive index of the same volume element after irradiation to the density of the dye molecules. The refractive index change per unit dye density has a unit of (centimeter)³. Thus in an embodiment, the optically readable datum includes at least one volume element wherein the ratio of the change in the refractive index per unit dye density of the at least one volume element to an absorption cross section of the photochemically active dye is at least about 10⁻⁵ expressed in units of centimeter.

Sensitivity (S) is a measure of the diffraction efficiency of a hologram recorded using a certain amount of light fluence (F). The light fluence (F) is given by the product of light intensity (i) and recording time (t). Mathematically, sensitivity may be expressed by Equation 3,

$$S = \frac{\sqrt{η}}{I \cdot t \cdot L} ( cm \text{/} J ) \qquad Equation 3$$

wherein “i” is the intensity of the recording beam, “t” is the recording time, L is the thickness of the recording (or data storage) medium (example, disc), and q is the diffraction efficiency. Diffraction efficiency is given by Equation 4,

$$η = {sin}^{2} ( \frac{π \cdot Δ n \cdot L}{λ \cdot cos ( θ )} ) \qquad Equation 4$$

wherein λ is the wavelength of light in the recording medium, θ is the recording angle in the media, and Δn is the refractive index contrast of the grating, which is produced by the recording process, wherein the dye molecule undergoes a photochemical conversion.

The absorption cross section is a measurement of an atom or molecule's ability to absorb light at a specified wavelength, and is measured in square cm/molecule. It is generally denoted by σ(λ) and is governed by the Beer-Lambert Law for optically thin samples as shown in Equation 5,

$$σ ( λ ) = ln ( 10 ) \cdot \frac{Absorbance ( λ )}{{N}_{o} \cdot L} ( {cm}^{2} ) \qquad Equation 5$$

wherein N₀ is the concentration in molecules per cubic centimeter, and L is the sample thickness in centimeters.

Quantum efficiency (QE) is a measure of the probability of a photochemical transition for each absorbed photon of a given wavelength. Thus, it gives a measure of the efficiency with which incident light is used to achieve a given photochemical conversion, also called as a bleaching process. QE is given by equation 6,

$$Q E = \frac{hc / λ}{σ \cdot {F}_{0}} \qquad Equation 6$$

wherein “h” is the Planck's constant, “c” is the velocity of light, σ(λ) is the absorption cross section at the wavelength λ, and F₀ is the bleaching fluence. The parameter F₀ is given by the product of light intensity (i) and a time constant (τ) that characterizes the bleaching process.

In one embodiment, the optically transparent substrate may have an absorbance of greater than 1 at a wavelength that is in a range of from about 300 nanometers to about 1000 nanometers. In one embodiment, without regard for thickness, the absorbance of the optically transparent substrate is in a range of from about 1.0 to about 1.1, from about 1.1 to about 1.2, or from about 1.2 to about 2.0, or greater at a wavelength that is in a range of from about 300 nanometers to about 1000 nanometers. In one embodiment, the optically transparent substrate may have an absorbance of greater than 1 at a wavelength that is in a range of from about 300 nanometers to about 500 nanometers, from about 500 nanometers to about 700 nanometers, or from about 700 nanometers to about 1000 nanometers.

In one embodiment, the amount of photochemically active dye present is in a range of about 0.1 weight percent to about 8 weight percent. In one embodiment, the amount of photochemically active dye present is in a range of about 2.5 weight percent to about 3 weight percent, of about 3 weight percent to about 3.5 weight percent, of about 3.5 weight percent to about 4 weight percent, 4 weight percent to about 4.5 weight percent, or of about 4.5 weight percent to about 5 weight percent.

In one embodiment, the optically transparent substrate is greater than about 20 micrometers thick. In one embodiment, the optically transparent substrate is about 20 micrometers to about 50 micrometers thick, about 50 micrometers to about 100 micrometers thick, about 100 micrometers to about 150 micrometers thick, about 150 micrometers to about 200 micrometers thick, about 200 micrometers to about 250 micrometers thick, or about 250 micrometers to about 300 micrometers thick, about 300 micrometers to about 350 micrometers thick, about 350 micrometers to about 400 micrometers thick, about 400 micrometers to about 450 micrometers thick, about 450 micrometers to about 500 micrometers thick, about 500 micrometers to about 550 micrometers thick, about 550 micrometers to about 600 micrometers thick, or greater.

A photochemically active dye may be described as a dye molecule that has an optical absorption resonance characterized by a center wavelength associated with the maximum absorption and a spectral width (full width at half of the maximum, FWHM) of less than 500 nanometers. In addition, the photochemically active dye molecule may undergo a partial light induced chemical reaction when exposed to light with a wavelength within the absorption range to form at least one photo-product. In various embodiments, this reaction may be a photo-decomposition reaction, such as oxidation, reduction, or bond breaking to form smaller constituents, or a molecular rearrangement, such as for example a sigmatropic rearrangement, or addition reactions including pericyclic cycloadditions. Thus in an embodiment, data storage in the form of holograms may be achieved wherein the photo-product is patterned (for example, in a graded fashion) within the modified optically transparent substrate to provide the at least one optically readable datum.

In various embodiments, the photochemically active dye (hereinafter sometimes referred to as “dye”) may be selected and utilized on the basis of several characteristics, including the ability to change the refractive index of the dye upon exposure to light; the efficiency with which the light creates the refractive index change; and the separation between the wavelength at which the dye shows a maximum absorption and the desired wavelength or wavelengths to be used for storing and/or reading the data. The choice of the photochemically active dye depends upon many factors, such as sensitivity (S) of the holographic recording media, concentration (N₀) of the photochemically active dye, the dye's absorption cross section (σ) at the recording wavelength, the quantum efficiency (QE) of the photochemical conversion of the dye, and the refractive index change per unit dye density (i.e., Δn/N₀). Of these factors, QE, Δn/N₀, and σ are more important factors which affect the sensitivity (S) and also information storage capacity (M/#). In one embodiment, photochemically active dyes that show a high refractive index change per unit dye density (Δn/N₀), a high quantum efficiency in the photochemical conversion step, and a low absorption cross-section at the wavelength of the electromagnetic radiation used for the photochemical conversion are selected.

In one embodiment, the photochemically active dye may be one that is capable of being written and read by electromagnetic radiation. In one embodiment, it may be desirable to use dyes that can be written (with a signal beam) and read (with a read beam) using actinic radiation i.e., radiation having a wavelength from about 300 nanometers to about 1000 nanometers. The wavelengths at which writing and reading may be accomplished may be in a range of from about 300 nanometers to about 800 nanometers. In one embodiment, the writing and reading are accomplished at a wavelength of about 400 nanometers to about 500 nanometers, at a wavelength of about 500 nanometers to about 550 nanometers, or at a wavelength of about 550 nanometers to about 600 nanometers. In one embodiment, the reading wavelength is shifted by a minimum amount of nanometers up to about 400 nanometers relative to the writing wavelength. Exemplary wavelengths at which writing and reading are accomplished are about 405 nanometers and about 532 nanometers.

As used herein, the term “aromatic radical” refers to an array of atoms having a valence of at least one including at least one aromatic group. The array of atoms having a valence of at least one including at least one aromatic group may include heteroatoms such as nitrogen, sulfur, selenium, silicon and oxygen, or may be composed exclusively of carbon and hydrogen. As used herein, the term “aromatic radical” includes but is not limited to phenyl, pyridyl, furanyl, thienyl, naphthyl, phenylene, and biphenyl radicals. As noted, the aromatic radical contains at least one aromatic group. The aromatic group is invariably a cyclic structure having 4n+2 “delocalized” electrons where “n” is an integer equal to 1 or greater, as illustrated by phenyl groups (n=1), thienyl groups (n=1), furanyl groups (n=1), naphthyl groups (n=2), azulenyl groups (n=2), anthraceneyl groups (n=3) and the like. The aromatic radical may also include nonaromatic components. For example, a benzyl group is an aromatic radical which includes a phenyl ring (the aromatic group) and a methylene group (the nonaromatic component). Similarly a tetrahydronaphthyl radical is an aromatic radical including an aromatic group (C₆H₃) fused to a nonaromatic component —(CH₂)₄—. For convenience, the term “aromatic radical” is defined herein to encompass a wide range of functional groups such as alkyl groups, alkenyl groups, alkynyl groups, haloalkyl groups, haloaromatic groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylphenyl radical is a C₇ aromatic radical including a methyl group, the methyl group being a functional group which is an alkyl group. Similarly, the 2-nitrophenyl group is a C₆ aromatic radical including a nitro group, the nitro group being a functional group. Aromatic radicals include halogenated aromatic radicals such as 4-trifluoro methyl phenyl, hexafluoro isopropylidene bis (4-phen-1-yloxy) (i.e., —OPhC(CF₃)₂PhO—); 4-chloromethylphen-1-yl, 3-trifluorovinyl-2-thienyl, 3-trichloro methylphen-1-yl (i.e., 3-CCl₃Ph-); 4-(3-bromoprop-1-yl)phen-1-yl (i.e., 4-BrCH₂CH₂CH₂Ph-); and the like. Further examples of aromatic radicals include 4-allyloxyphen-1-oxy; 4-aminophen-1-yl (i.e., 4-H₂NPh-); 3-aminocarbonylphen-1-yl (i.e., NH₂COPh-); 4-benzoylphen-1-yl; dicyano methylidene bis(4-phen-1-yl oxy) (i.e., —OPhC(CN)₂PhO—); 3-methylphen-1-yl, methylene bis(4-phen-1-yl oxy) (i.e., —OPhCH₂PhO—); 2-ethylphen-1-yl, phenyl ethenyl, 3-formyl-2-thienyl, 2-hexyl-5-furanyl; hexamethylene-1,6-bis (4-phen-1-yl oxy) (i.e., —OPh(CH₂)₆PhO—); 4-hydroxy methylphen-1-yl (i.e., 4-HOCH₂Ph-); 4-mercapto methylphen-1-yl (i.e., 4-HSCH₂Ph-); 4-methylthiophen-1-yl (i.e., 4-CH₃SPh-); 3-methoxyphen-1-yl; 2-methoxy carbonyl phen-1-yl oxy (e.g., methyl salicyl); 2-nitromethylphen-1-yl (i.e., 2-NO₂CH₂Ph); 3-trimethylsilylphen-1-yl; 4-t-butyl dimethylsilylphenl-1-yl; 4-vinylphen-1-yl; vinylidene bis(phenyl); and the like. The term “a C₃-C₁₀ aromatic radical” includes aromatic radicals containing at least three but no more than 10 carbon atoms. The aromatic radical 1-imidazolyl(C₃H₂N₂—) represents a C₃ aromatic radical. The benzyl radical (C₇H₇—) represents a C₇ aromatic radical.

As used herein the term “cycloaliphatic radical” refers to a radical having a valence of at least one, and including an array of atoms which is cyclic but which is not aromatic. As defined herein a “cycloaliphatic radical” does not contain an aromatic group. A “cycloaliphatic radical” may include one or more noncyclic components. For example, a cyclohexylmethyl group (C₆H₁₁CH₂—) is a cycloaliphatic radical which includes a cyclohexyl ring (the array of atoms which is cyclic but which is not aromatic) and a methylene group (the noncyclic component). The cycloaliphatic radical may include heteroatoms such as nitrogen, sulfur, selenium, silicon and oxygen, or may be composed exclusively of carbon and hydrogen. For convenience, the term “cycloaliphatic radical” is defined herein to encompass a wide range of functional groups such as alkyl groups, alkenyl groups, alkynyl groups, haloalkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methyl cyclopent-1-yl radical is a C₆ cycloaliphatic radical including a methyl group, the methyl group being a functional group which is an alkyl group. Similarly, the 2-nitrocyclobut-1-yl radical is a C₄ cycloaliphatic radical including a nitro group, the nitro group being a functional group. A cycloaliphatic radical may include one or more halogen atoms which may be the same or different. Halogen atoms include, for example; fluorine, chlorine, bromine, and iodine. Cycloaliphatic radicals including one or more halogen atoms include 2-trifluoro methylcyclohex-1-yl; 4-bromo difluoro methyl cyclo oct-1-yl; 2-chloro difluoro methylcyclohex-1-yl; hexafluoro isopropylidene-2,2-bis(cyclohex-4-yl) (i.e., —C₆H₁₀C(CF₃)₂C₆H₁₀—); 2-chloro methylcyclohex-1-yl; 3-difluoro methylene cyclohex-1-yl; 4-trichloro methyl cyclohex-1-yloxy; 4-bromo dichloro methylcyclohex-1-yl thio; 2-bromo ethyl cyclopent-1-yl; 2-bromo propyl cyclo hex-1-yloxy (e.g., CH₃CHBrCH₂C₆H₁₀O—); and the like. Further examples of cycloaliphatic radicals include 4-allyl oxycyclo hex-1-yl; 4-amino cyclohex-1-yl (i.e., H₂NC₆H₁₀—); 4-amino carbonyl cyclopent-1-yl (i.e., NH₂COC₅H₈—); 4-acetyl oxycyclo hex-1-yl; 2,2-dicyano isopropylidene bis(cyclohex-4-yloxy) (i.e., —OC₆H₁₀C(CN)₂C₆H₁₀O—); 3-methyl cyclohex-1-yl; methylene bis(cyclohex-4-yloxy) (i.e., —OC₆H₁₀CH₂C₆H₁₀O—); 1-ethyl cyclobut-1-yl; cyclo propyl ethenyl, 3-formyl-2-tetrahydrofuranyl; 2-hexyl-5-tetrahydrofuranyl; hexamethylene-1,6-bis (cyclohex-4-yloxy) (i.e., —OC₆H₁₀(CH₂)₆C₆H₁₀O—); 4-hydroxy methylcyclohex-1-yl (i.e., 4-HOCH₂C₆H₁₀—), 4-mercapto methyl cyclohex-1-yl (i.e., 4-HSCH₂C₆H₁₀—), 4-methyl thiocyclohex-1-yl (i.e., 4-CH₃SC₆H₁₀—); 4-methoxy cyclohex-1-yl, 2-methoxy carbonyl cyclohex-1-yloxy (2-CH₃OCOC₆H₁₀O—), 4-nitro methyl cyclohex-1-yl (i.e., NO₂CH₂C₆H₁₀—); 3-trimethyl silyl cyclohex-1-yl; 2-t-butyl dimethylsilylcyclopent-1-yl; 4-trimethoxy silylethyl cyclohex-1-yl (e.g., (CH₃O)₃SiCH₂CH₂C₆H₁₀—); 4-vinyl cyclohexen-1-yl; vinylidene bis(cyclohexyl), and the like. The term “a C₃-C₁₀ cycloaliphatic radical” includes cycloaliphatic radicals containing at least three but no more than 10 carbon atoms. The cycloaliphatic radical 2-tetrahydrofuranyl (C₄H₇O—) represents a C₄ cycloaliphatic radical. The cyclohexylmethyl radical (C₆H₁₁CH₂—) represents a C₇ cycloaliphatic radical.

As used herein the term “aliphatic radical” refers to an organic radical having a valence of at least one consisting of a linear or branched array of atoms which is not cyclic. Aliphatic radicals are defined to include at least one carbon atom. The array of atoms including the aliphatic radical may include heteroatoms such as nitrogen, sulfur, silicon, selenium and oxygen or may be composed exclusively of carbon and hydrogen. For convenience, the term “aliphatic radical” is defined herein to encompass, as part of the “linear or branched array of atoms which is not cyclic” a wide range of functional groups such as alkyl groups, alkenyl groups, alkynyl groups, haloalkyl groups, conjugated dienyl groups, alcohol groups, ether groups, aldehyde groups, ketone groups, carboxylic acid groups, acyl groups (for example carboxylic acid derivatives such as esters and amides), amine groups, nitro groups, and the like. For example, the 4-methylpent-1-yl radical is a C₆ aliphatic radical including a methyl group, the methyl group being a functional group which is an alkyl group. Similarly, the 4-nitrobut-1-yl group is a C₄ aliphatic radical including a nitro group, the nitro group being a functional group. An aliphatic radical may be a haloalkyl group which includes one or more halogen atoms which may be the same or different. Halogen atoms include, for example; fluorine, chlorine, bromine, and iodine. Aliphatic radicals including one or more halogen atoms include the alkyl halides trifluoromethyl; bromodifluoromethyl; chlorodifluoromethyl; hexafluoroisopropylidene; chloromethyl; difluorovinylidene; trichloromethyl; bromodichloromethyl; bromoethyl; 2-bromotrimethylene (e.g., —CH₂CHBrCH₂—); and the like. Further examples of aliphatic radicals include allyl; aminocarbonyl (i.e., —CONH₂); carbonyl; 2,2-dicyano isopropylidene (i.e., —CH₂C(CN)₂CH₂—); methyl (i.e., —CH₃); methylene (i.e., —CH₂—); ethyl; ethylene; formyl (i.e., —CHO); hexyl; hexamethylene; hydroxymethyl (i.e., —CH₂OH); mercaptomethyl (i.e., —CH₂SH); methylthio (i.e., —SCH₃); methylthiomethyl (i.e., —CH₂SCH₃); methoxy; methoxycarbonyl (i.e., CH₃OCO—) ; nitromethyl (i.e., —CH₂NO₂); thiocarbonyl; trimethylsilyl ( i.e., (CH₃)₃Si—); t-butyldimethylsilyl; 3-trimethyoxysilylpropyl (i.e., (CH₃O)₃SiCH₂CH₂CH₂—); vinyl; vinylidene; and the like. By way of further example, a C₁-C₁₀ aliphatic radical contains at least one but no more than 10 carbon atoms. A methyl group (i.e., CH₃—) is an example of a C₁ aliphatic radical. A decyl group (i.e., CH₃(CH₂)₉—) is an example of a C₁₀ aliphatic radical.

In one embodiment, the photochemically active dye may be a vicinal diarylethene. In one embodiment, the photochemically active dye may be a photo-product derived from a vicinal diarylethene. In one embodiment, the photochemically active dye may be a nitrone. In one embodiment, the photochemically active dye may be a nitrostilbene. Any combination having two or more members selected from the group consisting of a vicinal diarylethene, a nitrone, a photo-product derived from a vicinal diarylethene, and a nitrostilbene may also be used.

An exemplary class of vicinal diarylethene compounds are shown in the structure represented by Formula I:

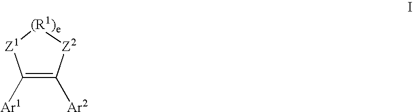

wherein “e” is 0 or 1; R¹ is a bond, an oxygen atom, a substituted nitrogen atom, a sulfur atom, a selenium atom, a divalent C₁-C₂₀ aliphatic radical, a halogenated divalent C₁-C₂₀ aliphatic radical, a divalent C₃-C₂₀ cycloaliphatic radical, a halogenated divalent C₁-C₂₀ cycloaliphatic radical, or a divalent C₂-C₃₀ aromatic radical; Ar¹ and Ar² are each independently a C₂-C₄₀ aromatic radical, or a C₂-C₄₀ heteroaromatic radical; and Z¹ and Z² are independently a bond, a hydrogen atom, a monovalent C₁-C₂₀ aliphatic radical, divalent C₁-C₂₀ aliphatic radical, a monovalent C₃-C₂₀ cycloaliphatic radical, a divalent C₃-C₂₀ cycloaliphatic radical, a monovalent C₂-C₃₀ aromatic radical, or a divalent C₂-C₃₀ aromatic radical. Table 1 below illustrates individual vicinal diarylethene compounds encompassed by the chemical genus represented by Formula I. The exemplary structures listed in the table each of the aromatic radicals Ar¹ and Ar² are identical as are the groups Z¹ and Z². Ar¹ may differ in structure from Ar² and that Z¹ may differ in structure from Z², and that such species are encompassed within Formula I and may be within the scope of the claims.

TABLE 1

| Example | R¹ | “e” | Ar¹ & Ar² | Z¹ & Z² |
|---|---|---|---|---|
| I-1 | 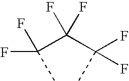 | 1 | 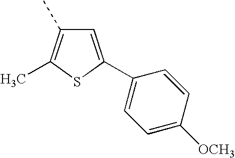 | bond |
| I-2 | 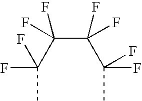 | 1 | 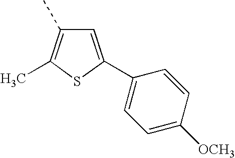 | bond |
| I-3 | 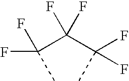 | 1 | 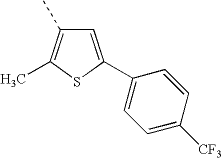 | bond |
| I-4 | 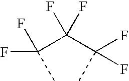 | 1 | 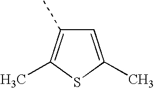 | bond |
| I-5 | — | 0 | 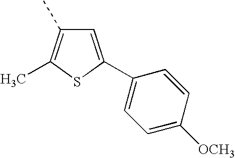 | CF₃ |
| I-6 | 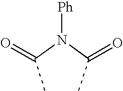 | 1 | 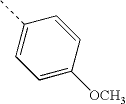 | bond |
| I-7 | 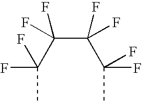 | 1 | 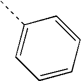 | bond |

In one embodiment, e is 0, and Z¹ and Z² are independently C₁-C₅ alkyl, C₁-C₅ perfluoroalkyl, or CN. In still another embodiment, e is 1, and Z¹ and Z² are independently CH₂, CF₂, or C═O. In yet another embodiment , Ar¹ and Ar² are each independently an aromatic radical selected from the group consisting of phenyl, anthracenyl, phenanthrenyl, pyridinyl, pyridazinyl, 1H-phenalenyl and naphthyl, optionally substituted by one or more substituents, wherein the substituents are each independently C₁-C₃ alkyl, C₁-C₃ perfluoroalkyl, C₁-C₃ alkoxy, or fluorine. In yet another embodiment at least one of Ar¹ and Ar² includes one or more aromatic moieties selected from the group consisting of structures II, III, and IV,

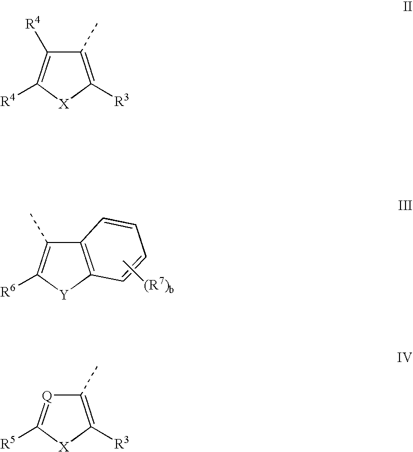

wherein R³, R⁴, R⁵, and R⁶ are hydrogen, a halogen atom, a nitro group, a cyano group, a C₁-C₁₀ aliphatic radical, a C₃-C₁₀ cycloaliphatic radical, or a C₂-C₁₀ aromatic radical; R⁷ is independently at each occurrence a halogen atom, a nitro group, a cyano group, a C₁-C₁₀ aliphatic radical, a C₃-C₁₀ cycloaliphatic radical, or a C₂-C₁₀ aromatic radical; “b” is an integer from and including 0 to and including 4; X and Y are selected from the group consisting of sulfur, selenium, oxygen, NH, and nitrogen substituted by a C₁-C₁₀ aliphatic radical, a C₃-C₁₀ cycloaliphatic radical, or a C₂-C₁₀ aromatic radical; and Q is CH or N. In one embodiment, at least one of R³, R⁴, R⁵, and R⁶ is selected from the group consisting of hydrogen, fluorine, chlorine, bromine, C₁-C₃ alkyl, C₁-C₃ perfluoroalkyl, cyano, phenyl, pyridyl, isoxazolyl, —CHC(CN)₂.

As mentioned previously, preferred photochemically active dyes are those that show a high refractive index change, a high quantum efficiency in the photochemical conversion step, and a low absorption cross-section at the wavelength of the electromagnetic radiation used for the photochemical conversion. One such example of a suitable photochemically active dye is illustrated by the vicinal diarylethene having Formula V,

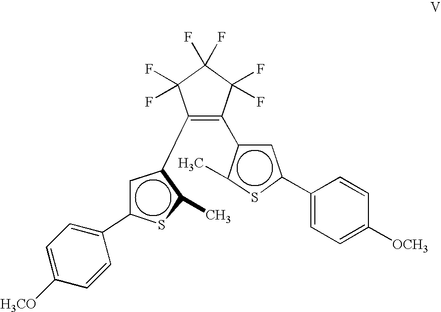

which is 1,2-bis{2-(4-methoxyphenyl)-5-methylthien-4-yl}-3,3,4,4,5,5-hexafluorocyclopent-1-ene. Vicinal diarylethene V shows a UV absorbance of about 1 at about 600 nanometers, the wavelength at which it cyclizes intramolecularly, and a high QE of about 0.8 for the cyclization step. Vicinal diarylethene V is also represented in the Table I above as Example I-1 wherein, with reference to generic structure I, R¹ is a perfluorotrimethylene group, “e” is 1, Z¹ and Z² are each bonds, and Ar¹ and Ar² are each 2-(4-methoxyphenyl)-5-methylthien-4-yl moieties.

Other examples of suitable vicinal diarylethenes that can be used as photochemically active dyes include diarylperfluorocyclopentenes, diarylmaleic anhydrides, diarylmaleimides, or a combination including at least one of the foregoing diarylethenes. The vicinal diarylethenes can be prepared using methods known in the art.

The vicinal diarylethenes can be reacted in the presence of actinic radiation (i.e. radiation that can produce a photochemical reaction), such as light. In one embodiment, an exemplary vicinal diarylethene can undergo a reversible cyclization reaction in the presence of light (hv) according to the following equation 7,

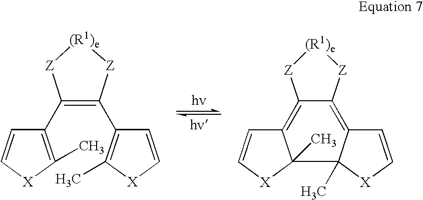

wherein X, Z R¹ and “e” have the meanings indicated above. The cyclization reactions can be used to produce holograms. The holograms can be produced by using radiation to effect the cyclization reaction or the reverse ring-opening reaction. Thus, in an embodiment, a photo-product derived from a vicinal diarylethene can be used as a photochemically active dye. Such photo-products derived from the vicinal diarylethene can be represented by a Formula VI,

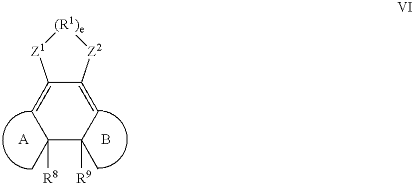

wherein “e”, R¹, Z¹, and Z² are as described for the vicinal diarylethene having Formula I, A and B are fused rings, and R⁸ and R⁹ are each independently a hydrogen atom, an aliphatic radical, a cycloaliphatic radical, or an aromatic radical. One or both fused rings A and B may include carbocyclic rings which do not have heteroatoms. In one embodiment, the fused rings A and B may include one or more heteroatoms selected from the group consisting of oxygen, nitrogen, and sulfur. Non-limiting examples of compounds falling within the scope of Formula VI include the compounds VII and VIII:

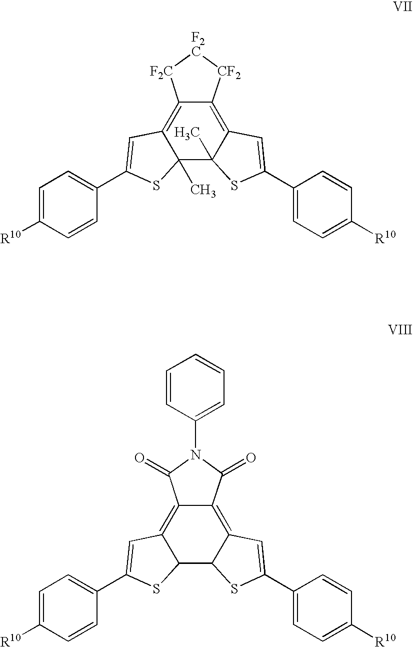

wherein R¹⁰ is independently at each occurrence a hydrogen atom, a methoxy radical, or a trifluoromethyl radical.

Nitrones may be used as photochemically active dyes for producing the holographic recording media. An exemplary nitrone may include an aryl nitrone structure represented by the Formula IX:

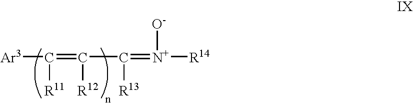

wherein Ar³ is an aromatic radical, each of R¹¹, R¹², and R¹³ is a hydrogen atom, an aliphatic radical, a cycloaliphatic radical, or an aromatic radical; R¹⁴ is an aliphatic radical (for example, an isopropyl) or an aromatic radical, and “n” is an integer having a value of from 0 to 4. In an embodiment, the radical R¹⁴ includes one or more electron withdrawing substituents selected from the group consisting of

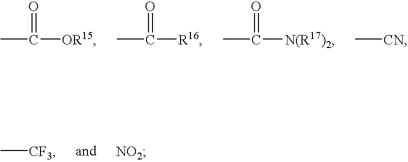

wherein R¹⁵-R¹⁷ are independently a C₁-C₁₀ aliphatic radical, a C₃-C₁₀ cycloaliphatic radical, or a C₂-C₁₀ aromatic radical.

As can be seen from Formula IX, the nitrones may be alpha-aryl-N-arylnitrones or conjugated analogs thereof in which the conjugation is between the aryl group and an alpha-carbon atom. The alpha-aryl group is frequently substituted, often by a dialkylamino group, in which the alkyl groups contain 1 to about 4 carbon atoms. Suitable, non-limiting examples of nitrones include alpha-(4-diethylaminophenyl)-N-phenylnitrone; alpha-(4-diethylaminophenyl)-N-(4-chlorophenyl)-nitrone, alpha-(4-diethylaminophenyl)-N-(3,4-dichlorophenyl)-nitrone, alpha-(4-diethylaminophenyl)-N-(4-carbethoxyphenyl)-nitrone, alpha-(4-diethylaminophenyl)-N-(4-acetylphenyl)-nitrone, alpha-(4-dimethylaminophenyl)-N-(4-cyanophenyl)-nitrone, alpha-(4-methoxyphenyl)-N-(4-cyanophenyl)nitrone, alpha-(9-julolidinyl)-N-phenylnitrone, alpha-(9-julolidinyl)-N-(4-chlorophenyl)nitrone, alpha-(4-dimethylamino)styryl-N-phenylnitrone, alpha-styryl-N-phenyl nitrone, alpha-[2-(1,1-diphenylethenyl)]-N-phenylnitrone, alpha-[2-(1-phenylpropenyl)]-N-phenylnitrone, 2,5-thiophene-bis-2-ethylhexylesterphenyl dinitrone; or a combination including at least one of the foregoing nitrones. In one embodiment, the photochemically active dye is alpha-(4-dimethylamino)styryl-N-phenylnitrone. In one embodiment, the photochemically active dye is 2,5-thiophene-bis-2-ethylhexylesterphenyl dinitrone.

In one embodiment, the photochemically active dye is a nitrostilbene compound. Nitrostilbene compounds are illustrated by 4-dimethylamino-2′,4′-dinitrostilbene, 4-dimethylamino-4′-cyano-2′-nitrostilbene, 4-hydroxy-2′,4′-dinitrostilbene, and the like. The nitrostilbene can be a cis isomer, a trans isomer, or mixtures of the cis and trans isomers. Thus, In one embodiment, the photochemically active dye useful for producing a holographic recording medium includes at least one member selected from the group consisting of 4-dimethylamino-2′,4′-dinitrostilbene, 4-dimethylamino-4′-cyano-2′-nitrostilbene, 4-hydroxy-2′,4′-dinitrostilbene, 4-methoxy-2′,4′-dinitrostilbene, alpha-(4-diethylaminophenyl)-N-phenylnitrone; alpha-(4-diethylaminophenyl)-N-(4-chlorophenyl)-nitrone, alpha-(4-diethylaminophenyl)-N-(3,4-dichlorophenyl)-nitrone, alpha-(4-diethylaminophenyl)-N-(4-carbethoxyphenyl)-nitrone, alpha-(4-diethylaminophenyl)-N-(4-acetylphenyl)-nitrone, alpha-(4-dimethylaminophenyl)-N-(4-cyanophenyl)-nitrone, alpha-(4-methoxyphenyl)-N-(4-cyanophenyl)nitrone, alpha-(9-julolidinyl)-N-phenylnitrone, alpha-(9-julolidinyl)-N-(4-chlorophenyl)nitrone, alpha-[2-(1,1-diphenylethenyl)]-N-phenylnitrone, and alpha-[2-(1-phenylpropenyl)]-N-phenylnitrone.

Upon exposure to electromagnetic radiation, nitrones undergo unimolecular cyclization to an oxaziridine illustrated by Formula X,

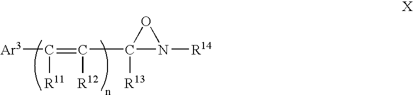

wherein Ar³, R¹¹-R¹⁴, and n have the same meaning as denoted above for the Formula IX.

The optically transparent substrate used in producing the holographic recording media may include any plastic material having sufficient optical quality, e.g., low scatter, low birefringence, and negligible losses at the wavelengths of interest, to render the data in the holographic recording material readable. Organic polymeric materials, such as for example, oligomers, polymers, dendrimers, ionomers, copolymers such as for example, block copolymers, random copolymers, graft copolymers, star block copolymers; or the like, or a combination including at least one of the foregoing polymers can be used. Thermoplastic polymers or thermosetting polymers can be used. Examples of suitable thermoplastic polymers include polyacrylates, polymethacrylates, polyamides, polyesters, polyolefins, polycarbonates, polystyrenes, polyesters, polyamideimides, polyarylates, polyarylsulfones, polyethersulfones, polyphenylene sulfides, polysulfones, polyimides, polyetherimides, polyetherketones, polyether etherketones, polyether ketone ketones, polysiloxanes, polyurethanes, polyarylene ethers, polyethers, polyether amides, polyether esters, or the like, or a combination including at least one of the foregoing thermoplastic polymers. Some more possible examples of suitable thermoplastic polymers include, but are not limited to, amorphous and semi-crystalline thermoplastic polymers and polymer blends, such as: polyvinyl chloride, linear and cyclic polyolefins, chlorinated polyethylene, polypropylene, and the like; hydrogenated polysulfones, ABS resins, hydrogenated polystyrenes, syndiotactic and atactic polystyrenes, polycyclohexyl ethylene, styrene-acrylonitrile copolymer, styrene-maleic anhydride copolymer, and the like; polybutadiene, polymethylmethacrylate (PMMA), methyl methacrylate-polyimide copolymers; polyacrylonitrile, polyacetals, polyphenylene ethers, including, but not limited to, those derived from 2,6-dimethylphenol and copolymers with 2,3,6-trimethylphenol, and the like; ethylene-vinyl acetate copolymers, polyvinyl acetate, ethylene-tetrafluoroethylene copolymer, aromatic polyesters, polyvinyl fluoride, polyvinylidene fluoride, and polyvinylidene chloride.

In some embodiments, the thermoplastic polymer used in the methods disclosed herein as a substrate is made of a polycarbonate. The polycarbonate may be an aromatic polycarbonate, an aliphatic polycarbonate, or a polycarbonate including both aromatic and aliphatic structural units.

As used herein, the term “polycarbonate” includes compositions having structural units of the Formula XI:

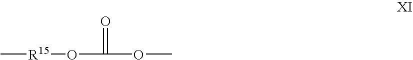

wherein R¹⁵ is an aliphatic, aromatic or a cycloaliphatic radical. In an embodiment, the polycarbonate includes structural units of the Formula XII:

-A¹-Y¹-A²- XII

wherein each of A¹ and A² is a monocyclic divalent aryl radical and Y¹ is a bridging radical having zero, one, or two atoms which separate A¹ from A². In an exemplary embodiment, one atom separates A¹ from A². Non-limiting examples of radicals include —O—, —S—, —S(O)—, —S(O)₂—, —C(O)—, methylene, cyclohexyl-methylene, 2-ethylidene, isopropylidene, neopentylidene, cyclohexylidene, cyclopentadecylidene, cyclododecylidene, and adamantylidene. Some examples of such bisphenol compounds are bis(hydroxyaryl)ethers such as 4,4′-dihydroxy diphenylether, 4,4′-dihydroxy-3,3′-dimethylphenyl ether, or the like; bis(hydroxy diaryl)sulfides, such as 4,4′-dihydroxy diphenyl sulfide, 4,4′-dihydroxy-3,3′-dimethyl diphenyl sulfide, or the like; bis(hydroxy diaryl) sulfoxides, such as, 4,4′-dihydroxy diphenyl sulfoxides, 4,4′-dihydroxy-3,3′-dimethyl diphenyl sulfoxides, or the like; bis(hydroxy diaryl)sulfones, such as 4,4′-dihydroxy diphenyl sulfone, 4,4′-dihydroxy-3,3′-dimethyl diphenyl sulfone, or the like; or combinations including at least one of the foregoing bisphenol compounds. In one embodiment, zero atoms separate A¹ from A², with an illustrative example being biphenol. The bridging radical Y¹ can be a hydrocarbon group, such as, for example, methylene, cyclohexylidene or isopropylidene, or aryl bridging groups.

Any of the dihydroxy aromatic compounds known in the art can be used to make the polycarbonates. Examples of dihydroxy aromatic compounds include, for example, compounds having general structure XIII:

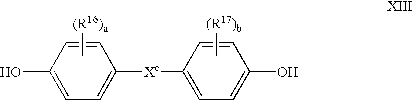

wherein R¹⁶ and R¹⁷ each independently represent a halogen atom, or a aliphatic, aromatic, or a cycloaliphatic radical; a and b are each independently integers from 0 a to 4; and X^{c} represents one of the groups of structure XIV:

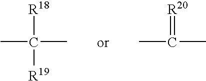

wherein R¹⁸ and R¹⁹ each independently represent a hydrogen atom or a aliphatic, aromatic or a cycloaliphatic radical; and R²⁰ is a divalent hydrocarbon group. Some illustrative, non-limiting examples of suitable dihydroxy aromatic compounds include dihydric phenols and the dihydroxy-substituted aromatic hydrocarbons such as those disclosed by name or structure (generic or specific) in U.S. Pat. No. 4,217,438. Polycarbonates including structural units derived from bisphenol A may be selected since they are relatively inexpensive and commercially readily available. A nonexclusive list of specific examples of the types of bisphenol compounds that may be represented by structure (XIII) includes the following: 1,1-bis(4-hydroxyphenyl)methane; 1,1-bis(4-hydroxyphenyl)ethane; 2,2-bis(4-hydroxyphenyl)propane (hereinafter “bisphenol A” or “BPA”); 2,2-bis(4-hydroxyphenyl)butane; 2,2-bis(4-hydroxyphenyl)octane; 1,1 -bis(4-hydroxyphenyl)propane; 1,1-bis(4-hydroxyphenyl)n-butane; bis(4-hydroxyphenyl)phenylmethane; 2,2-bis(4-hydroxy-3-methylphenyl)propane (hereinafter “DMBPA”); 1,1-bis(4-hydroxy-t-butylphenyl)propane; bis(hydroxyaryl) alkanes such as 2,2-bis(4-hydroxy-3-bromophenyl) propane; 1,1-bis(4-hydroxyphenyl)cyclopentane; 9,9′-bis(4-hydroxyphenyl)fluorene; 9,9′-bis(4-hydroxy-3-methylphenyl)fluorene; 4,4′-biphenol; and bis(hydroxyaryl)cycloalkanes such as 1,1-bis(4-hydroxyphenyl)cyclohexane and 1,1-bis(4-hydroxy-3-methylphenyl)cyclohexane (hereinafter “DMBPC”); and the like, as well as combinations including at least one of the foregoing bisphenol compound.

Polycarbonates can be produced by any of the methods known in the art. Branched polycarbonates are also useful, as well as blends of linear polycarbonates and branched polycarbonates. In one embodiment, the polycarbonates may be based on bisphenol A. In one embodiment, the weight average molecular weight of the polycarbonate is about 5,000 to about 100,000 atomic mass units. In one embodiment, the weight average molecular weight of the polycarbonate is about 5000 to about 10000 atomic mass units, about 10000 to 20000 atomic mass units, about 20000 to 40000 atomic mass units, about 40000 to 60000 atomic mass units, about 60000 to 80000 atomic mass units, or about 80000 to 100000 atomic mass units. Other specific examples of a suitable thermoplastic polymer for use in forming the holographic recording media include Lexan®, a polycarbonate; and Ultem®, an amorphous polyetherimide, both of which are commercially available from General Electric Company.

Examples of useful thermosetting polymers include those selected from the group consisting of an epoxy, a phenolic, a polysiloxane, a polyester, a polyurethane, a polyamide, a polyacrylate, a polymethacrylate, and a combination including at least one of the foregoing thermosetting polymers.

In one embodiment, the photochemically active dye may be admixed with other additives to form a photo-active material. Examples of such additives include heat stabilizers; antioxidants; light stabilizers; plasticizers; antistatic agents; mold releasing agents; additional resins; binders, blowing agents; and the like, as well as combinations of the foregoing additives. In one embodiment, the photo-active materials may be used for manufacturing holographic recording media.

In one embodiment, a holographic recording medium is provided. The holographic recording medium includes an optically transparent substrate. The optically transparent substrate includes an optically transparent plastic material, and a photochemically active dye. The optically transparent substrate has an absorbance of greater than 1 at a wavelength that is in a range of from about 300 nanometers to about 1000 nanometers. The holograms recorded in the optically transparent substrate are capable of having diffraction efficiencies of greater than about 20 percent. Upon exposure to light, the photo-product is patterned within the optically transparent substrate to provide an optically readable datum contained within a volume of the holographic recording medium.

In one embodiment, the optically readable datum includes a volume element having a refractive index that differs from a corresponding volume element of the optically transparent substrate. The volume element may be characterized by a change in refractive index relative to the refractive index of the corresponding volume element prior to the at least one photo-product being patterned.

In one embodiment, a holographic recording medium is made. The method includes irradiating an optically transparent substrate including a photochemically active dye with an incident light at a wavelength in a range of from about 300 nanometers to about 1000 nanometers at which the optically transparent substrate has an absorbance of greater than 1, and resulting in forming the holographic recording medium including an optically readable datum and a photo-product of a photochemically active dye. The hologram recorded in the optically transparent substrate has a diffraction efficiency of greater than about 20 percent.

In one embodiment, an optical writing and reading method is provided. The method includes simultaneously patterning a holographic recording medium with a signal beam possessing data and with a reference beam. At least a portion of the photochemically active dye partly converts to a photo-product. The signal beam data is stored as a hologram in the holographic recording medium. The holographic recording medium can be contacted with a read beam to read the data contained in light diffracted by the hologram. The holographic recording medium can include an optically transparent substrate as disclosed herein.

In one embodiment, a method includes subjecting a holographic recording medium in the holographic recording article to an electromagnetic radiation having a first wavelength, forming a modified optically transparent substrate including at least one photo-product of the photochemically active dye, and at least one optically readable datum stored as a hologram, and contacting the holographic recording medium in the article with electromagnetic energy having a second wavelength to read the hologram. The holographic recording medium includes an optically transparent substrate. The optically transparent substrate includes an optically transparent plastic material, and a photochemically active dye. The optically transparent substrate has an absorbance of greater than about 1 at a wavelength that is in a range of from about 300 nanometers to about 1000 nanometers. The optically readable datum recorded in the optically transparent substrate has a diffraction efficiency of greater than about 20 percent.

In one embodiment, the second wavelength is shifted by an amount in a range of from about 0 nanometer to about 400 nanometers relative to the first wavelength. In one embodiment, the first wavelength is not the same as the second wavelength. In one embodiment, the first wavelength is the same as the second wavelength.

In one embodiment, a method includes forming a film, an extrudate, or an injection molded part of an optically transparent substrate. The optically transparent substrate includes an optically transparent plastic material and a photochemically active dye. The optically transparent substrate has an absorbance of greater than 1 at a wavelength in a range of from about 300 nanometers to about 1000 nanometers. The holograms recorded in the optically transparent substrate are capable of having diffraction efficiencies of greater than about 20 percent. The film formation may include thermoplastic extruding. The film formation may include thermoplastic molding. The film formation may include spin casting.

In one embodiment, a holographic recording medium is provided. The holographic recording medium includes an optically transparent substrate. The optically transparent substrate includes an optically transparent plastic material and a photochemically active dye. The optically transparent substrate has an absorbance of greater than 1 when irradiated with an incident light at a wavelength that is in a range of from about 300 nanometers to about 1000 nanometers to write a hologram. The hologram in the optically transparent substrate is capable of having diffraction efficiency of greater than about 20 percent.

### EXAMPLES

The following examples illustrate methods and embodiments in accordance with the invention, and as such should not be construed as imposing limitations upon the claims. Unless specified otherwise, all components are commercially available from common chemical suppliers such as Alpha Aesar, Inc. (Ward Hill, Mass.), Spectrum Chemical Mfg. Corp. (Gardena, Calif.), and the like.

### Example 1

### Preparation of a Dye

### Step A: Preparation of phenylhydroxylamine.

Ammonium chloride (20.71 grams, 0.39 moles), de-ionized water (380 milliliters), nitrobenzene (41.81 grams, 0.34 moles), and ethanol (420 milliliters, 95 percent) are added to a 1-liter, 3-necked round-bottomed flask equipped with a mechanical stirrer, thermometer, and nitrogen inlet. The resultant reaction mixture is cooled to 15 degrees Celsius using an ice water bath. Zinc powder (46.84 grams, 0.72 moles) is added to the cooled mixture in portions, and over a period of about 0.5 hours while ensuring that the temperature does not exceed 25 degrees Celsius. After the complete addition of the zinc, the reaction mixture is warmed to room temperature. The warmed mixture is stirred for a half an hour and is then filtered to remove zinc salt and unreacted zinc. The filter cake (i.e., the zinc salt) is first washed with hot water (about 200 milliliters) and then is washed with methylene chloride (about 100 milliliters). The filtrate is extracted with methylene chloride (about 100 milliliters). The methylene chloride layers (obtained from the filter cake wash and filtrate extract) are combined, washed with brine (about 100 milliliters), dried over sodium sulfate, and the methylene chloride is evaporated. The product is dried in a vacuum oven for about 24 hours to give 17.82 grams of phenylhydroxylamine as a fluffy light yellow solid.

### Step B: Preparation of alpha-(4-dimethylamino)styryl-N-phenyl nitrone

To a 1 liter, 3 neck round-bottomed flask equipped with a mechanical stirrer and a nitrogen inlet is added phenylhydroxyamine (27.28 grams, 0.25 moles), 4-dimethylaminocinnamaldehyde (43.81 grams, 0.25 moles) and ethanol (250 milliliters) resulting in a bright orange colored mixture. To the resultant mixture, methanesulfonic acid (250 microliters) is added using a syringe. The resultant mixture turns to a deep red color solution with the dissolution of all the solids. Within about five minutes an orange solid is formed. Pentane (˜300 ml) is added to the mixture to facilitate stirring. The solid is filtered and dried in a vacuum oven at 80 degrees Celsius for about 24 hours to give 55.91 grams of alpha-(4-dimethylamino)styryl-N-phenylnitrone as a bright orange solid.

### Example 2

### Preparation of Dye

### Step A: Preparation of 4-hydroxyaminobenzoicacid-2-ethylhexyl ester

To a 500 milliliters 3-neck flask is added p-nitrophenyl-2-ethylhexyl ester (14 grams), ethanol (50 milliliters), ammonium chloride (3.1 grams), and water (50 milliliters). To the resultant mixture zinc (7.3 grams) is slowly added over a period of about 0.5 hours and the resulting mixture is stirred at room temperature for about 5 hours. The mixture is filtered and the filter cake is washed with methylene chloride. The organic phase is separated from the resultant filtrate, dried over sodium sulfate, and the methylene chloride is evaporated to provide 5.6 grams of 4-hydroxyaminobenzoicacid-2-ethylhexyl ester.

### Step B: Preparation of 2,5-thiophene-bis-2-ethylhexylesterphenyl dinitrone.

To a 250 ml 3-neck flask is added 2,5 thiophenedicarboxy-aldehyde (1.2 grams), acetic acid (100 milliliters), and 4-hydroxyaminobenzoicacid-2-ethylhexyl ester (11.4 grams). The resultant mixture is stirred for about 20 hours at about 25 degrees Celsius. De-ionized water (100 milliliters) is added to the resultant mixture. The precipitated solids are filtered, washed with water, and dried to obtain 3.5 grams of crude 2,5-thiophene-bis-2-ethylhexylesterphenyl dinitrone.

### Step C : Purification 2,5-thiophene-bis-2-ethylhexylesterphenyl dinitrone.

500 grams of the crude 2,5-thiophene-bis-2-ethylhexylesterphenyl dinitrone is stirred with 600 milliliters of a solvent mixture having 25 percent ethyl acetate and 75 percent n-hexane for about 10 minutes and filtered. The solvents are distilled out from the filtrate. The resultant solid is again stirred with 50 milliliters of a solvent mixture having 10 percent ethyl acetate and 90 percent n-hexane, and the resultant mixture is filtered to obtain 250 milligrams of pure 2,5-thiophene-bis-2-ethylhexylesterphenyl dinitrone.

### Example 3

### Preparation of Dye—Polymer Mixture

Ten kilograms of pelletized polystyrene PS 1301 (obtained from Nova Chemicals) is ground to a coarse powder in a Retsch mill and dried in a circulating oven maintained at 80 degrees Celsius for 12 hours. In a 10 liter Henschel mixer, 6.5 kilograms of the dry polystyrene powder and 195 grams of alpha-(4-dimethylamino)styryl-N-phenyl nitrone are blended to form a homogeneous orange powder. The powder is fed into a Prism (16 mm) twin-screw extruder at 185 degrees Celsius to give 6.2 kilograms of dark orange colored pellets with a dye content of about 3 weight percent. This material is further diluted with additional crystal polystyrene 1301 pellets to make blends having 1 weight percent and 3 weight percent of dye. Each of these four diluted blend compositions are re-processed with the Prism (16 mm) twin-screw extruder to form homogeneously colored pellets. The conditions used for extruding are included in Table 2.

TABLE 2

| EXTRUSION PARAMETERS | VALUES |
|---|---|
| Screw (revolutions per minute) | 300 |
| Feeder Rate (units) | 4.8-6.3 (at 50 percent) |
| Torque (percent) | 68-72 |
| Temp Zone 1 (degrees Celsius) | 160-200 |
| Temp Zones 2-9 (degrees Celsius) | 170-190 |

### Example 4

### Preparation of Dye—Polymer Mixture

The 2,5-thiophene bis 2-ethylhexylesterphenyl dinitrone-polystyrene blends are prepared in a manner similar to that described in Example 3, except in that 2,5-thiophene bis 2-ethylhexylesterphenyl dinitrone is used as the dye and blends having 2 weight percent, 3 weight percent, 3.2 weight percent, and 4 weight percent of the dye are prepared.

The extruded pellets obtained in Example 3 and Example 4 are dried in vacuum oven at temperatures of nearly 40 degrees Celsius below the glass transition temperature of the polymer. Optical quality discs are prepared by injection molding the four diluted blends (prepared as described above) with a Sumitomo, SD-40E all-electrical commercial CD/DVD (compact disc/digital video disc) molding machine (available from Sumitomo Inc.). The molded discs have a thickness in a range from about 500 micrometers to about 1200 micrometers. Mirrored stampers are used for both surfaces. Cycle times are generally set to about 10 seconds. Molding conditions are varied depending upon the glass transition temperature and melt viscosity of the polymer used, as well as the photochemically active dye's thermal stability. Thus the maximum barrel temperature is controlled to be in a range of from about 200 degrees Celsius to about 375 degrees Celsius. The molded discs are collected and stored in the dark.

### Example 5

### Preparation of a Molded Disc

Conditions used for molding OQ (Optical Grade) polystyrene based blends of the photochemically active dyes are shown in Table 3.

TABLE 3
Parameters

| | POLYSTYRENE |
|---|---|
| MOLDING PARAMETERS | BLEND |
| Barrel Temperature (Rear) (degrees Celsius) | 205 |
| Barrel Temperature (Front) (degrees Celsius) | 200 |
| Barrel Temperatuer (Nozzle) (degrees Celsius) | 200 |
| Melt Temperature (degrees Celsius) | 200-250 |
| Mold Temperature (degrees Celsius) | 50-70 |
| Total cycle Time (sec) | 3-12 |
| Switch Point (inch) | 0.7 |
| Injection Transition (inch) | 0.2 |
| Injection Boost Pressure (psi) | 1100 |
| Injection Hold pressure (psi) | 400 |
| Injection Velocity (millimiter per second) | 60-150 |

### Example 6

### Procedure for Preparing Solvent Cast Samples

A set of polystyrene pellets (1 gram) are dissolved in 10 milliliters of methylene chloride and stirred for about 2 hours or till the polystyrene pellets are completely dissolved in the methylene chloride. A dye ((4-dimethylamino)styryl-N-phenyl nitrone (50 milligrams)) is added to the polymer solution and stirred for about 2 hours or till the nitrone is completely dissolved in the methylene chloride. Solvent cast samples are made by pouring the dye-polystyrene solution inside a metal ring (5 centimeter radius) resting over a glass substrate. The assembly of the metal ring placed over the glass substrate is placed over a hot plate maintained at a temperature of about 40 degrees Celsius. The assembly is covered with an inverted funnel to allow slow evaporation of methylene chloride. Dried dye-doped polystyrene films were recovered after about 4 hours. The dye-doped polystyrene films contained 5 and 8 weight percent of the dye.

### Example 7

### Sample Evaluation

Procedure for measuring UV-visible spectra of the photochemically active dyes. All spectra are recorded on a Cary/Varian 300 UV-visible spectrophotometer using injection-molded discs having a thickness of about 1.2 millimeters. Spectra are recorded in the range of 300 nanometers to 800 nanometers. Due to disc-to-disc variations, no reference sample was used. The reported values are corrected for background absorption and surface reflections.

The absorption reported in the tables is calculated by subtracting the average baseline in the range of 700 to 800 nanometers for each sample tested from the measured absorption at either 405 nanometers or 532 nanometers. Since these compounds do not absorb in the 700 to 800 nanometers range, this correction removes the apparent absorption caused by reflections off the surfaces of the disc and provides a more accurate representation of the absorbance of the dye. The polymers used in these examples have little or no absorption at 405 nanometers or 532 nanometers.

### Example 8

### Method of Use

Procedure for recording of the hologram on molded disc or solvent cast samples.

For recording of the hologram at either 532 nanometers or 405 nanometers, both the reference beam and the signal beam are incident on the test sample at oblique angles of 45 degrees. The sample is positioned on a rotary stage, which is controlled by a computer. Both the reference and signal beams have the same optical power and are polarized in the same direction (parallel to the sample surface). The beam diameters (1/e²) are 4 millimeters. A color filter and a small pinhole are placed in front of the detector to reduce optical noise from the background light. A fast mechanical shutter in front of the laser controls the hologram recording time. In the 532 nanometers setup, a red 632 nanometers beam is used to monitor the dynamics during hologram recording. The recording power for each beam varies from 1 milliwatt to 100 milliwatt and the recording time varies from 10 milliseconds to about 5 seconds. The diffracted power from a recorded hologram is measured from a Bragg detuning curve by rotating the sample disc by 0.2 to 0.4 degrees. The reported values are corrected for reflections off the sample surface. The power used to readout the holograms is two to three orders of magnitude lower than the recording power in order to minimize hologram erasure during readout. Results of the UW-visible absorption spectra measurements and the diffraction efficiencies of the two dyes prepared in Example 3 and Example 4 that are used for preparing the discs in Example 5 are included in Table 4 and Table 5 below. Results of the of the UW-visible absorption spectra measurements and the diffraction efficiencies of the dye used to prepare the solvent cast samples in Example 6 are included in Table 6 below.

TABLE 4
Results
Example 3: alpha-(4-dimethylamino)styryl-N-phenyl nitrone

| | |
|---|---|
| Diffraction | Dye loading in |
| Efficiency | weight percent |

| Corrected (red) | 1 | 3 |
|---|---|---|
| Maximum | 10.54 | 68.92 |
| Average | 6.351 | 49.86 |
| Absorbance | 0.3 | 1.1 |

Thickess of disc = 600 micrometers

TABLE 5
Results
Example 4: 2,5-thiophene bis 2-ethylhexylesterphenyl dinitrone

| | |
|---|---|
| Diffraction | Dye loading in |
| Efficiency | weight percent |

| Corrected (red) | 2 | 3 | 3.2 | 4 |
|---|---|---|---|---|
| Maximum | 23.47 | 35.88 | 38.74 | 43.2 |
| Average | 15.28 | 24.83 | 29.06 | 34.4 |
| Absorbance | 0.54 | 1.0 | 1.1 | 1.4 |

Thickness of disc = 600 micrometers

TABLE 6
Results
Example 5: (4-dimethylamino)styryl-N-phenyl nitrone

| Diffraction | Dye loading in | | |
|---|---|---|---|
| Efficiency | weight percent | | |
| Corrected (red) | 5 | 5 | 8 |
| Maximum | 58.11 | 23 | 33.4 |
| Average | 55 | 21.2 | 27.6 |
| Absorbance | 1.15 | 1.6 | 1.5 |
| Thickness | 150 | 210 | 120 |
| (micrometers) | | | |

The data in Table 4 for 3 weight percent of the dye, in Table 5 for 3, 3.2, and 4 weight percent of the dye, and in Table 6 for 5 and 8 weight percent of the dye show that an absorbance of greater than 1 at a wavelength that is in a range from about 300 nanometers to about 800 nanometers and a hologram with a diffraction efficiency of greater than about 20 or higher may be achieved by using from about 0.1 to about 8 weight percent of a dye, based on a total weight of the optically transparent substrate. However, the weight percent of the dye that is needed to obtain the desired results is dependent on the type of dye being employed. This is understood from the data in Table 4 for 1 and 2 weight percent and in Table 5 for 2 weight percent of the dye, where the absorbance is less than 1 though the diffraction efficiency of the hologram is greater than 20 percent. The thickness of the sample also plays a role in the value of the absorbance and the diffraction efficiency as seen in Table 6 for the samples with 5 weight percent dye and thickness of 150 micrometers and 210 micrometers respectively.

Certain dyes, for example, 2,5-thiophene-bis-2-butylesterphenyl dinitrone demonstrate an absorbance of greater than 1 at dye loadings of less than 1 weight percent. The amount of dye used and the resultant absorbance obtained may be such that the resultant optically transparent substrate may be transparent at a wavelength that is in a range of from about 300 nanometers to about 1000 nanometers. Dyes that result in opaque substrates may not be desirable since the opaque substrates may be incapable of producing holograms with diffraction efficiencies greater than about 20 percent. One skilled in the art can determine the type of dye, amount of dye and thickness of the sample required to obtain an optically transparent substrate having an absorbance of greater than 1 at a wavelength that is in a range of from about 300 nanometers to about 1000 nanometers; and that is capable of having a diffraction efficiency of greater than about 20 percent.

The singular forms “a”, “an”, and “the” include plural referents unless the context clearly dictates otherwise. “Optional” or “optionally” means that the subsequently described event or circumstance may or may not occur, and that the description includes instances where the event occurs and instances where it does not. Approximating language, as used herein throughout the specification and claims, may be applied to modify any quantitative representation that could permissibly vary without resulting in a change in the basic function to which it is related. Accordingly, a value modified by a term or terms, such as “about” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. Molecular weight ranges disclosed herein refer to molecular weight as determined by gel permeation chromatography using polystyrene standards.

While the invention has been described in detail in connection with a number of embodiments, the invention is not limited to such disclosed embodiments. Rather, the invention can be modified to incorporate any number of variations, alterations, substitutions or equivalent arrangements not heretofore described, but which are commensurate with the scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

1. A holographic recording medium comprising:
an optically transparent substrate comprising an optically transparent plastic material and a photochemically active dye; and
the optically transparent substrate has an absorbance of greater than 1 at a wavelength that is in a range of from about 300 nanometers to about 1000 nanometers; and
the holograms recorded in the optically transparent substrate are capable of having diffraction efficiencies of greater than about 20 percent.

2. The holographic recording medium of claim 1, having a data storage capacity that is greater than about 1.

3. The holographic recording medium of claim 1, wherein the amount of photochemically active dye present is in a range of about 0.1 weight percent to about 8 weight percent based on a total weight of the optically transparent substrate.

4. The holographic recording medium of claim 1, wherein the optically transparent substrate is greater than about 20 micrometers thick.

5. The holographic recording medium of claim 1, wherein a photochemically active dye comprises a vicinal diarylethene.

6. The holographic recording medium of claim 1, wherein a photochemically active dye comprises a nitrone.

7. The holographic recording medium of claim 1, wherein the photochemically active dye comprises a nitrostilbene.

8. The holographic recording medium of claim 1, wherein the photochemically active dye is selected from the group consisting of 4-dimethylamino-2+,4′-dinitrostilbene; 4-dimethylamino-4′-cyano-2′-nitrostilbene; 4-hydroxy-2′,4′-dinitrostilbene; 4-methoxy-2′,4′-dinitrostilbene; alpha-(4-diethylaminophenyl)-N-phenylnitrone; alpha(4-diethylaminophenyl)-N-(4-chlorophenyl)-nitrone; alpha (4-diethylaminophenyl)-N-(3,4-dichlorophenyl)-nitrone; alpha (4-diethylaminophenyl)-N-(4-carbethoxyphenyl)-nitrone; alpha (4-diethylaminophenyl)-N-(4-acetylphenyl)-nitrone; alpha(4-dimethylaminophenyl)-N-(4-cyanophenyl)nitrone; alpha(4-methoxyphenyl)-N-(4-cyanophenyl)nitrone; alpha(9-julolidinyl)-N-phenylnitrone; alpha(9-julolidinyl)-N-(4-chlorophenyl)nitrone; alpha(4-dimethylamino)styryl-N-phenylnitrone; alpha-styryl-N-phenylnitrone; alpha(2-(1,1-diphenylethenyl))-N-phenylnitrone; alpha-(2-(1-phenylpropenyl))-N-phenylnitrone; and 1,2 bis(2-(4-methoxyphenyl)-5-methylthien-4-yl)-3,3,4,4,5,5-hexafluorocyclopent-1-ene.

9. The holographic recording medium of claim 1, wherein the optically transparent substrate comprises a thermoplastic polymer, a thermosetting polymer, or a combination of a thermoplastic polymer and a thermosetting polymer.

10. A holographic recording medium, comprising:
an optically transparent substrate comprising an optically transparent plastic material, a photochemically active dye, and a photo-product thereof, and
the optically transparent substrate has an absorbance of greater than 1 at a wavelength that is in a range of from about 300 nanometers to about 1000 nanometers; and
the hologram recorded in the optically transparent substrate has a diffraction efficiency of greater than about 20 percent; and
the photo-product defines a pattern within the optically transparent substrate to provide an optically readable datum contained within a volume of the holographic recording medium.

11. The holographic recording medium of claim 10, wherein the optically readable datum comprises a volume element having a refractive index that differs from a corresponding volume element of the optically transparent substrate, said volume element being characterized by a change in refractive index relative to the refractive index of the corresponding volume element prior to the at least one photo-product being patterned.

12. The holographic recording medium of claim 10, having a data storage capacity of greater than 1.

13. The holographic recording medium of claim 10, wherein the amount of photochemically active dye present is in a range of about 0.1 weight percent to about 8 weight percent.

14. A method, comprising:
irradiating an optically transparent substrate comprising a photochemically active dye with an incident light that has a wavelength in a range of from about 300 nanometers to about 1000 nanometers, and at which the wavelength the optically transparent substrate has an absorbance of greater than 1; and
forming a holographic recording medium comprising an optically readable datum and a photo-product of a photochemically active dye, and a hologram recorded in the optically transparent substrate has a diffraction efficiency of greater than about 20 percent.

15. The method of claim 14, wherein the photo-product is patterned within the modified optically transparent substrate to provide at least one optically readable datum.

16. An optical writing and reading method, comprising:
patterning a holographic recording medium simulataneously with a signal beam possessing data and with a reference beam to create a hologram, and thereby at least partly converting a photochemically active dye into a photo-product;
storing the signal beam data in a hologram in the holographic recording medium, and the holographic recording medium comprises an optically transparent substrate comprising an optically transparent plastic material and one or both of the photochemically active dye or the photo-product, and the optically transparent substrate has an absorbance of greater than 1 at a wavelength that is in a range of from about 300 nanometers to about 1000 nanometers, and the hologram recorded in the optically transparent substrate has a diffraction efficiency of greater than about 20 percent; and
contacting the holographic recording medium with a read beam and reading the data contained by light that is diffracted by the hologram.

17. The method of claim 16, wherein the read beam has a wavelength that is shifted by an amount up to about 400 nanometers relative to the signal beam's wavelength.

18. A method, comprising:
subjecting a holographic recording medium in the holographic recording article to an electromagnetic radiation having a first wavelength;
forming a modified optically transparent substrate comprising at least one photo-product of the photochemically active dye, and at least one optically readable datum stored as a hologram; and
contacting the holographic recording medium in the article with electromagnetic energy having a second wavelength to read the hologram; and
and the holographic recording medium comprises an optically transparent substrate comprising an optically transparent plastic material, a photochemically active dye, and a photo-product of a photochemically active dye; the optically transparent substrate has an absorbance of greater than 1 at a wavelength that is in a range of from about 300 nanometers to about 1000 nanometers; and the hologram recorded in the optically transparent substrate has a diffraction efficiency of greater than about 20 percent

19. The method of claim 18, further comprising shifting the second wavelength by an amount up to about 400 nanometers relative to the first wavelength.

20. The method of claim 18, wherein the first wavelength is not the same as the second wavelength.

21. The method of claim 18, wherein the first wavelength is the same as the second wavelength.

22. A method, comprising
forming a film, an extrudate, or an injection molded part that is capable of use as holographic recording medium that is an optically transparent substrate that comprises both an optically transparent plastic material and a photochemically active dye, wherein
the optically transparent substrate has an absorbance of greater than 1 at a wavelength in a range of from about 300 nanometers to about 1000 nanometers, and the holograms recorded in the optically transparent substrate are capable of having diffraction efficiencies of greater than about 20 percent.

23. The method of claim 22, wherein forming the film comprises solvent casting.

24. The method of claim 22, wherein forming the molded part comprises thermoplastic molding

25. The method of claim 22, wherein forming the extrudate comprises thermoplastic extrusion.

26. A holographic recording medium comprising:
an optically transparent substrate comprising an optically transparent plastic material and a photochemically active dye; and
the optically transparent substrate has an absorbance of greater than 1 when irradiated with an incident light at a wavelength that is in a range of from about 300 nanometers to about 1000 nanometers to write a hologram; and
the holograms recorded in the optically transparent substrate have diffraction efficiencies of greater than about 20 percent.
